(19) United States
(12) Patent Application Publication
(10) Pub. No.: US 2012/0064375 A1
(43) Pub. Date: Mar. 15, 2012

(54) METHOD FOR MANUFACTURING A PERPENDICULAR MAGNETIC DATA RECORDING MEDIA HAVING A PSEUDO ONSET LAYER

(75) Inventors: Gunn Choe, San Jose, CA (US); Yoshihiro Ikeda, San Jose, CA (US)

(73) Assignee: Hitachi Global Storage Technologies Netherlands B. V., Amsterdam (NL)

(21) Appl. No.: 12/882,123

(22) Filed: Sep. 14, 2010

(51) Int. Cl. G11B 5/667; C23C 14/34; B05D 5/00

(52) U.S. Cl. 428/828.1; 427/127; 204/192.15; 427/131; 428/827

(57) ABSTRACT

A method for manufacturing a magnetic media for perpendicular magnetic data recording. The method includes depositing a Ru layer in a pure oxygen atmosphere and then further depositing Ru in the presence of oxygen to form a thin pseudo onset layer. The pseudo onset layer can advantageously be depositing in the same deposition chamber and using the same target as that used to deposit the underlying Ru layer. This saves a great deal of manufacturing cost and complexity. The presence of the pseudo onset layer reduces grains size and increases grain separation in a high Ku magnetic layer deposited thereon, thereby increasing signal to noise ratio and decreasing magnetic core width (MCW).

### FIELD OF THE INVENTION

The present invention relates to magnetic heads for data recording, and more particularly to a low cost method for manufacturing a magnetic media having a pseudo onset layer for improved magnetic properties in the hard magnetic layer of the media.

### BACKGROUND OF THE INVENTION

The heart of a computer's long term memory is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located on a slider that has an air bearing surface (ABS). The suspension arm biases the slider toward the surface of the disk, and when the disk rotates, air adjacent to the disk moves along with the surface of the disk. The slider flies over the surface of the disk on a cushion of this moving air. When the slider rides on the air bearing, the write and read heads are employed for writing magnetic transitions to and reading magnetic transitions from the rotating disk. The read and write heads are connected to processing circuitry that operates according to a computer program to implement the writing and reading functions.

A giant magnetoresistive (GMR) or tunnel junction magnetoresistive (TMR) sensor senses magnetic fields from the rotating magnetic disk. The sensor includes a nonmagnetic conductive layer, or barrier layer, sandwiched between first and second ferromagnetic layers, referred to as a pinned layer and a free layer. First and second leads are connected to the sensor for conducting a sense current there-through. The magnetization of the pinned layer is pinned perpendicular to the air bearing surface (ABS) and the magnetic moment of the free layer is located parallel to the ABS, but free to rotate in response to external magnetic fields. The magnetization of the pinned layer is typically pinned by exchange coupling with an antiferromagnetic layer.

In a perpendicular magnetic recording system, the magnetic media has a magnetically soft underlayer covered by a thin magnetically hard top layer. The perpendicular write head has a write pole with a very small cross section and a return pole having a much larger cross section. A strong, highly concentrated magnetic field emits from the write pole in a direction perpendicular to the magnetic disk surface, magnetizing the magnetically hard top layer. The resulting magnetic flux then travels through the soft underlayer, returning to the return pole where it is sufficiently spread out and weak that it will not erase the signal recorded by the write pole when it passes back through the magnetically hard top layer on its way back to the return pole.

In order for the perpendicular magnetic recording media to operate at high data densities, the magnetically hard top layer is preferably thermally stable and preferably has the desired high coercivity. The magnetically hard top layer also preferably has a small grain size which promotes high signal to noise ratio and small magnetic core width. What's more these properties are preferably achieved by a process that is manufacturable at low cost and high throughput.

### SUMMARY OF THE INVENTION

The present invention provides a method for manufacturing a magnetic disk drive that includes placing a disk in a deposition tool that contains a Ru target, and then filling the deposition tool with an Ar atmosphere. A first deposition is then performed using the Ru target in the Ar atmosphere to form a Ru layer. Then, a mixture of Ar and oxygen is pumped into the chamber and a second deposition is performed using the Ru target in the Ar and oxygen atmosphere to form a pseudo onset layer over the Ru layer. Then, a magnetic oxide is deposited onto the pseudo onset layer.

The invention forms a magnetic media that has a pseudo onset layer that advantageously reduces grain size and increases grain separation in a hard magnetic oxide layer deposited thereover.

This pseudo onset layer can advantageously be deposited in the same deposition chamber and using the same target as that used to deposit the underlying Ru layer. This saves considerably manufacturing cost and complexity, and also allows the magnetic media layers to be deposited in an older, less expensive deposition tool having less deposition chambers than would be necessary if the pseudo onset layer were constructed of a material that is different from the underlying layer.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is an enlarged, cross sectional view of a portion of a magnetic media manufactured according to the present invention;

FIG. 3 is a schematic illustration of a sputter deposition tool in which a deposition process according to the present invention can be implemented;

FIG. 4 is a graph illustrating sputter deposition atmospheres used in an implementation of the present invention;

FIG. 5 is an enlarged view of a Ru layer and a magnetic oxide layer without a pseudo onset layer; and

FIG. 6 is an enlarged view of a Ru under-layer, pseudo onset layer and a magnetic oxide layer formed over the pseudo onset layer;

FIG. 7 is a graph showing a relationship between Isolated Signal to Noise Ratio (SoNR) and the Ku value of a magnetic oxide layer;

FIG. 8 is a graph showing a relationship between Magnetic Core Width and the Ku value of a magnetic oxide layer; and

FIG. 9 is a table showing various magnetic properties and signal properties for a magnetic medium having for various oxygen flow rates during deposition of a Ru under-layer.

### DETAILED DESCRIPTION OF THE EMBODIMENTS

The following description is of the best embodiments presently contemplated for carrying out this invention. This description is made for the purpose of illustrating the general principles of this invention and is not meant to limit the inventive concepts claimed herein.

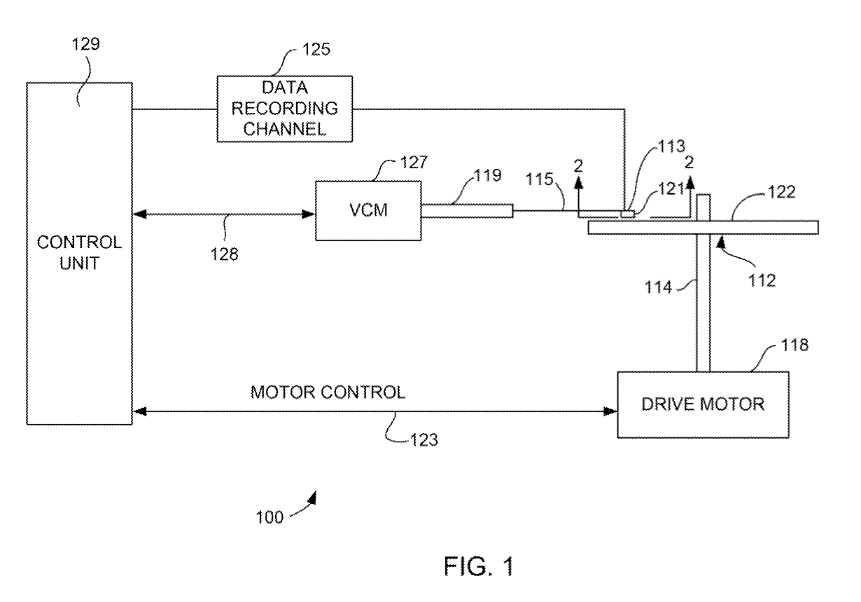

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, the slider 113 moves radially in and out over the disk surface 122 so that the magnetic head assembly 121 may access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122 which exerts an upward force or lift on the slider. The air bearing thus counter-balances the slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

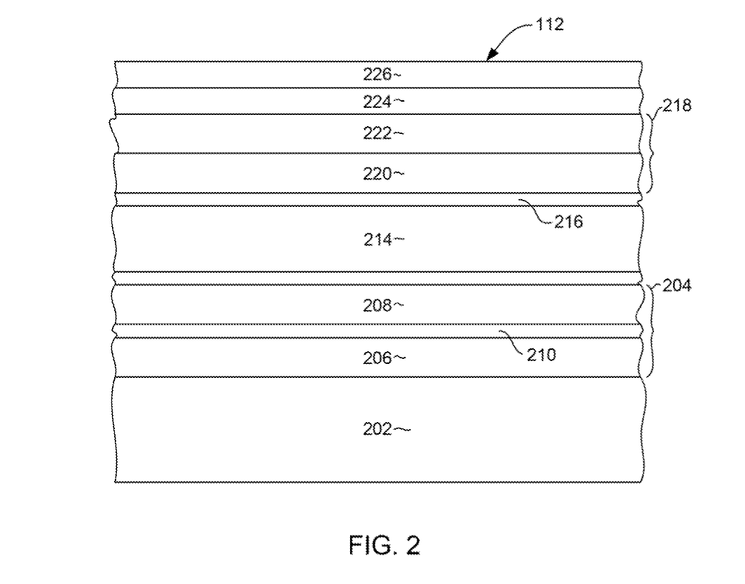

FIG. 2 shows an enlarged cross section of a magnetic media 112 for use in a perpendicular magnetic recording system. The media 112 includes a substrate 202, which can be a glass or an alumina metal alloy. A soft magnetic layer structure 204 is formed on top of the substrate 202. The soft magnetic layer structure can be an antiparallel coupled structure including first and second low coercivity magnetic layers 206, 208 such as CoFe, with a non-magnetic antiparallel coupling layer such as Ru 210 sandwiched there-between. A seed layer 212 is provided over the soft magnetic under-layer 204. The seed layer can be a material such as NiW, NiWCr or NiFeW, which is chosen to promote a desired grain growth on layers 214, 216, deposited thereon. A Ru under-layer 214 is then formed on the seed layer 212, and a pseudo-onset layer 216 is formed directly on top of the under-layer. As can be seen, the Ru under-layer 214 is substantially thicker than the pseudo-onset layer 216. The pseudo-onset layer 216 is constructed of oxidized Ru (like the under-layer 214), which advantageously allows the pseudo-onset layer to be deposited in the same sputtering chamber using the same Ru target as that used to deposit the under-layer. This saves manufacturing time and complexity, and also allows both the under-layer 214 and the pseudo-onset layer 216 to be deposited using an older, less expensive sputter deposition tool having less chambers than a newer, more expensive sputtering tool.

The Ru under-layer 214 can be doped with a small amount of an element X, where X is one or more of Ti, Ta, B, Cr or Si. Similarly, the pseudo onset layer 216 can also be doped with a small amount of the element X, where X is one or more of Ti, Ta, B, Cr or Si. The pseudo onset layer 216 has the same composition as the Ru under-layer, except for the addition of oxygen.

A hard magnetic top layer structure 218 is formed over the pseudo-onset layer 216. The hard magnetic layer can include first and second magnetic oxide layers 220, 222. The first layer 220 is a high Ku magnetic oxide, and the second layer 222 is a lower Ku magnetic oxide. The bottom, high Ku magnetic oxide layer 220 preferably has a Ku value of 5×10⁵ erg/cc. The high Ku magnetic oxide layer 220 can be constructed of CoPCr plus one or more oxides such as SiO₂, Ta₂O₅ or TiO₂. The layer 222 can be a similar material, but having a higher percentage of Cr and oxides. The layer 222 can also contain Ru, B or some other non-magnetic material to reduce the Ku value. A capping layer 224, such as Ta, can be provided over the layer 222 and a protective overcoat 226, such as carbon, can be provided over the capping layer.

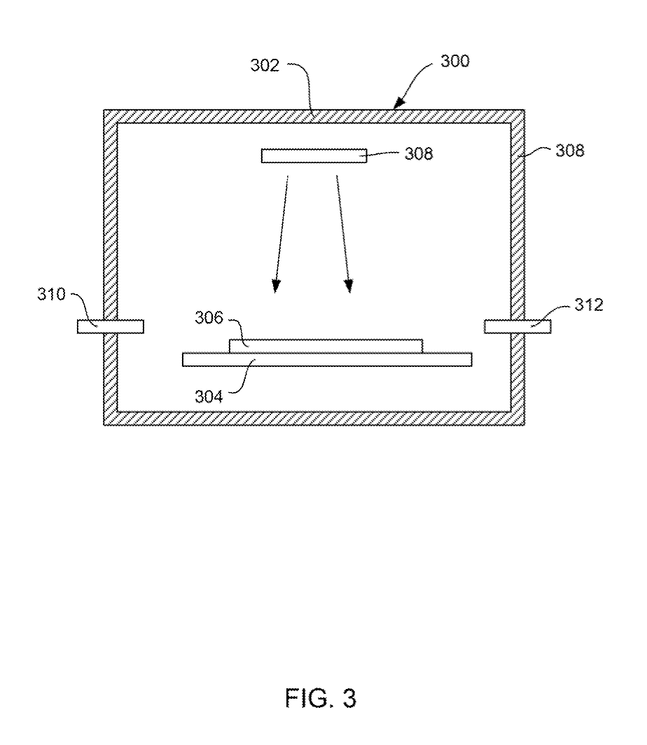

The Ru layer 214 and pseudo onset layer 216 can be deposited by sputter deposition in a sputter deposition tool such as is shown schematically in FIG. 3. FIG. 3 shows a sputter deposition tool 300 that includes a chamber 302. A platter 304 holds a disk 306 on which the Ru layer 214 and pseudo onset layer 216 (FIG. 2) are to be deposited. A Ru target 308 is also held within the chamber 302, arranged in such a manner that atoms dislodged from the target 308 can be deposited onto the disk 306 when a plasma is struck within the chamber 302.

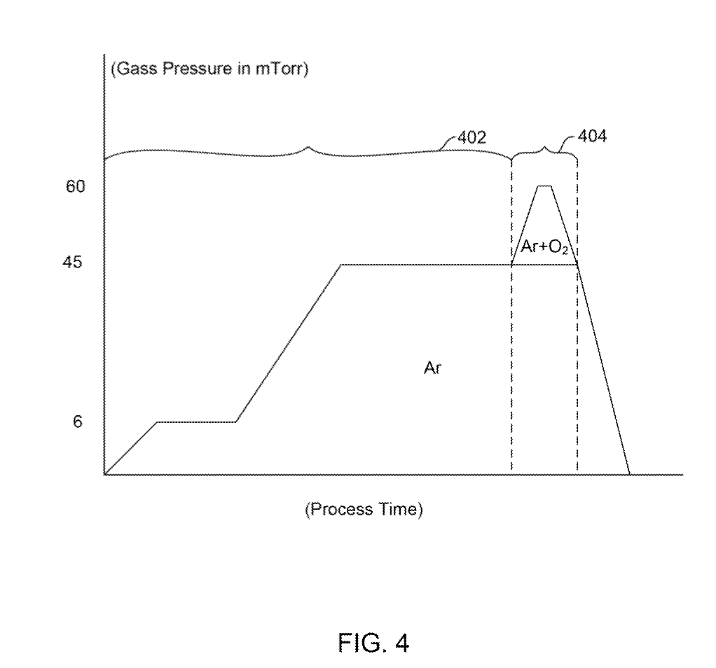

The chamber also includes a gas inlet 310 and gas outlet 312. To deposit the Ru layer 214 (FIG. 2), Ar gas is pumped into the chamber so that the chamber is essentially pure Ar. This Ar gas is preferably at a pressure of 5 mTorr-50 mTorr. The Ar pressure is significantly changed in the middle of the 214 layer deposition. This can be seen more clearly with reference to FIG. 4, which shows a graph of gas pressure within the chamber as a function of process time. The section 402 of the graph represents the process time in which the Ru layer 214 is deposited. After the Ru layer 214 has been deposited to a desired thickness (such as 10-25 nm), a combination of Ar and O₂ is added to the chamber 302. This corresponds to section 404 of the graph of FIG. 4 wherein it can be seen that Ar+O₂ has been added to the pure Ar atmosphere within the chamber 302. In section 402 of the graph, the Ru is deposited first at a relatively low pressure, and then at an intermediate pressure. Then, in the section 404, the Ru oxide is deposited at a relatively higher pressure. In section 404 of the graph, a gas that is about 95 atomic percent Ar and 5 atomic percent oxygen (e.g. 90-98% Ar and 2-10% oxygen) is added to the chamber, which already contains an Ar atmosphere. This addition of Ar and oxygen preferably results in an atmosphere within the chamber that is 90-99 atomic percent Ar and 1-10 atomic percent oxygen.

The addition of the Ar and O₂ to the chamber allows the pseudo onset layer 216 (FIG. 2) to be deposited as a Ru oxide layer. As can be seen, the pseudo onset layer 216 can be deposited without any need to change the target 308 and without the need to move the disk 306 into another chamber. This greatly reduces manufacturing cost and complexity.

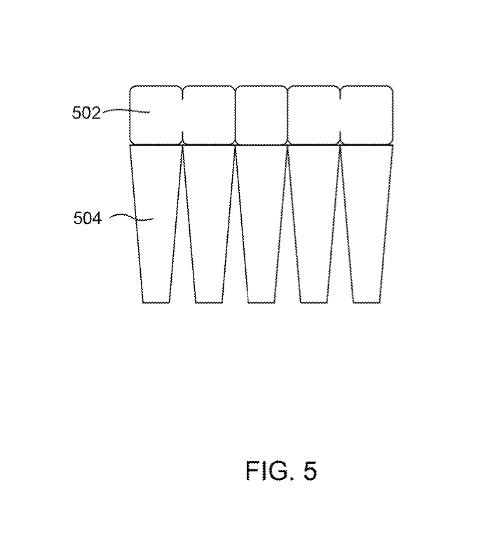

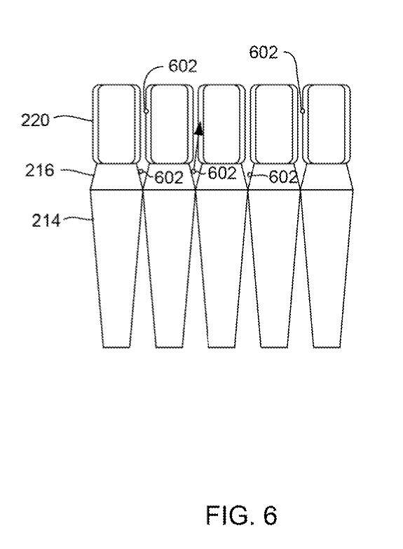

The addition of Ar+O₂ in the chamber makes the Ru grain structure of the pseudo onset layer 216 smaller and more separated than the Ru layer 214. This grain feature is also transferred onto the high Ku layer 220. This can be better understood with reference to FIGS. 5 and 6. FIG. 5 shows a grain structure in which the present invention has not been implemented. In FIG. 5, a high Ku layer 502 is deposited directly on a Ru layer 504 without a pseudo onset layer. As can be seen in FIG. 5, the grains of the high Ku layer are not well separated and even join together resulting in poor magnetic bit separation.

FIG. 6, on the other hand, illustrates a structure wherein the present invention has been implemented, adding oxygen to the deposition of the Ru layer as described above. With reference to FIG. 6, the Ru layer has a pseudo onset later 216 formed thereon by the above described method. The presence of oxygen makes the Ru grains smaller and better separated. The pseudo onset layer 216 has a smaller grain size than the under-layer 214 and has a larger grain boundary than the under-layer 214. The pseudo onset layer 216 preferably has a grain size of 6-8 nm, whereas the under-layer 214 preferably has a grain size of 8-10 nm. This grain feature is also transferred to the above deposited Ku layer 220. This makes media noise smaller. In order to take advantage of the benefits of the pseudo onset layer 316, the high Ku layer 220 preferably has a Ku value that is greater than 5×10⁵ erg/cc. The second magnetic oxide layer 222 preferably has a lower Ku value, preferably 1×10⁵ erg/cc to 4×10⁵ erg/cc.

In FIG. 6, the Ru layer 214 was sputtered at low pressure first to promote good crystal orientation. Then, after that, the gas pressure is increased to get the well separated grain structure of FIG. 216. Since the good grain separation can be obtained with relatively thick total Ru thickness, the grain size of the top of the Ru layer 214 tends to be large. The addition of Ar and oxygen interferes with the lateral growth and makes the top layer 216 smaller and rougher. In addition to this effect, Ru does not react easily with oxygen. That causes the oxygen atoms 602 to be weakly trapped to the Ru grain boundary during the deposition of layer 216. Then, when the high Ku layer 220 is deposited on the structure, the trapped oxygen atoms in the Ru boundary will selectively oxidize the grain boundary of the high Ku layer. That also separates the grains magnetically and reduces the medium noise. This effect is more effective when the layer 220 is deposited right after pseudo onset layer deposition.

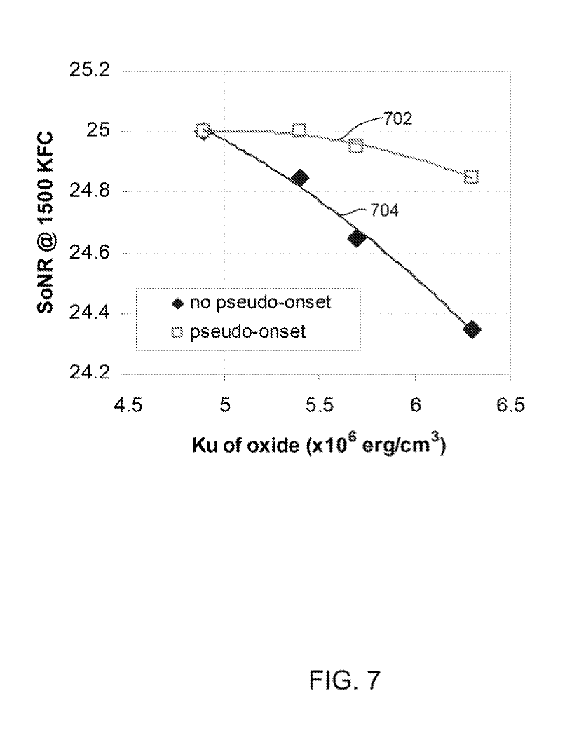

FIG. 7 is a graph that shows the relationship between Isolated Signal to Noise Ratio (SoNR) and the Ku value of the oxide layer 220 (FIGS. 2 and 6). The curve 702 shows SoNR values for a media having the pseudo onset layer, and curve 704 shows the SoNR values for a media without the pseudo onset layer. As can be seen, the SoNR values drop off dramatically in a media that does not employ the pseudo onset layer of the present invention, while the SoNR value drops very little when the pseudo onset layer of the present invention is employed. This shows that the benefit of the pseudo onset layer increases with increasing Ku of the oxide layer 220.

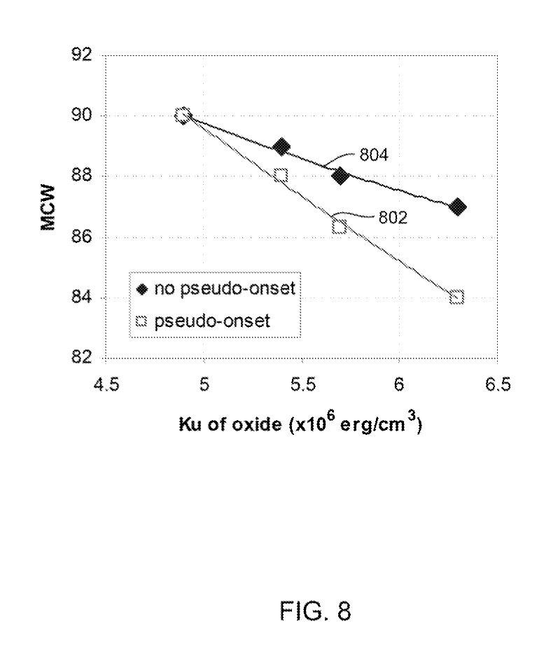

FIG. 8 is a graph showing the relationship between Magnetic Core Width (MCW) and the Ku value of the oxide layer 220. Line 802 shows the MCW for a media having the pseudo onset layer of the present invention, and line 804 shows the MCW for a media without the pseudo onset layer. As can be seen, the MCW shrinks faster with increasing Ku of the oxide layer 220 in a media employing the pseudo onset layer. This is because of the smaller grain size. This smaller MCW of the media employing the pseudo onset layer means that smaller bits can be recorded, which in turn increases data density. It can also be seen that this benefit increases with increasing Ku of the oxide layer 220.

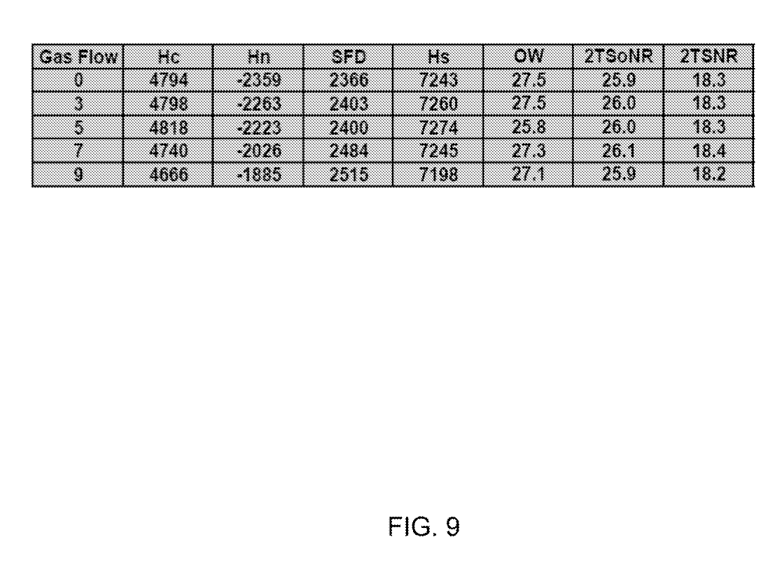

The table in FIG. 9 shows how various properties of the magnetic oxide layer 220 (FIG. 2) vary with varying Ar+O₂ flow rates during deposition of the pseudo onset layer 216. More particularly the table shows the dependence of Hc, Hn, SFD and Hs as well as properties of the recording data. When the flow rate is of the Ar+O₂ is 0 there is no pseudo onset layer. The Hc shows the peak at the middle at around 5 sccm and Hn decreases with the gas flow. The SNR increases with gas flow rate without increasing the Magnetic Core Width (MCW). Because the Kerr loop slope parameter SFD also increases with the Ar+O₂ flow, the magnetic grains are well separated by the Ar+O₂ flow. The data also indicates that the recording performance is improved by increasing the gas flow and shows an optimum around 5-7 sccm.

While various embodiments have been described above, it should be understood that they have been presented by way of example only, and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a magnetic disk drive, comprising:
placing a disk in a deposition tool containing a target that comprises Ru;
filling the deposition tool with an Ar atmosphere;
performing a first deposition using the target in the Ar atmosphere to form an under-layer;
pumping a mixture of Ar and oxygen into the deposition tool;
performing a second deposition using the target in the Ar and oxygen atmosphere to form a pseudo onset layer over the under-layer; and
depositing a magnetic oxide onto the pseudo onset layer.

2. The method as in claim 1 wherein the first deposition is performed at a first pressure and the second deposition is performed at a second pressure that is greater than the first pressure.

3. The method as in claim 1 wherein the first deposition is performed at a pressure of 5-50 mTorr and the second deposition is performed at a pressure of 51-70 mRorr.

4. The method as in claim 1 wherein the first deposition is performed in an atmosphere it is only Ar and the second deposition is performed while introducing a mixture of 95% Ar and 5% O₂.

5. The method as in claim 1 wherein the first sputter deposition is performed in an atmosphere that is only Ar and the second sputter deposition is performed in an atmosphere that contains 90 to 99 atomic percent Ar and 1-10 atomic percent oxygen.

6. The method as in claim 1 wherein the under-layer is deposited to a thickness of 10-25 nm.

7. The method as in claim 1 wherein the grain size of the pseudo onset layer is larger than the grain size of the under-layer.

8. The method as in claim 1 wherein the grain size of the pseudo onset layer is 6-8 nm and the grain size of the under-layer is 8-10 nm.

9. The method as in claim 1 wherein the magnetic oxide has a Ku value of at least 5×10⁵ erg/cc.

10. The method as in claim 1 wherein the magnetic oxide layer is a first magnetic oxide layer, the method further comprising after depositing the first magnetic oxide layer, depositing a second magnetic oxide layer, the first magnetic oxide layer having a higher Ku value than the second magnetic oxide layer.

11. The method as in claim 1 wherein the magnetic oxide layer is a first magnetic oxide layer, the method further comprising after depositing the first magnetic oxide layer, depositing a second magnetic oxide layer, the first magnetic oxide layer having a higher Ku value of at least 5×10⁵ erg/cc, and the second magnetic oxide layer has a Ku value of 1×10⁵ erg/cc to 4×10⁵ erg/cc.

12. The method as in claim 1 wherein the pseudo onset layer has a grain boundary size that is larger than a grain boundary size of the under-layer.

13. The method as in claim 1 wherein the target comprises Ru+X, where X is Ti, Ta, B, Cr or Si.

14. The method as in claim 13 wherein the target contains no more than 3 atomic percent X.

15. A magnetic media for magnetic data recording, comprising:
a soft magnetic layer structure;
an under-layer comprising Ru formed over the soft magnetic layer structure;
a pseudo onset layer formed over the under-layer, the pseudo onset layer comprising Ru with added oxygen; and
a magnetic oxide formed over the pseudo onset layer.

16. The magnetic media as in claim 15, wherein the pseudo onset layer has 95-99 atomic percent Ru and 1-5 atomic percent oxygen.

17. The magnetic media as in claim 15 wherein the under-layer has a thickness of 10-25 nm and the pseudo onset layer has a thickness of 0.5-5 nm.

18. The magnetic media as in claim 15 wherein the magnetic oxide layer has a Ku value of at least 5×10⁵ erg/cc.

19. The magnetic media as in claim 15 wherein the magnetic oxide layer comprises a first magnetic oxide layer formed directly on the pseudo oxide layer and having a Ku value of at least 5×10⁵ erg/cc and a second magnetic oxide layer formed directly on the first magnetic oxide layer and having a Ku value less than that of the first magnetic oxide layer.

20. The magnetic media as in claim 15 wherein the soft magnetic layer structure comprises first and second magnetic layers and a non-magnetic antiparallel coupling layer sandwiched between the first and second magnetic layers.

21. The magnetic media as in claim 15, wherein the pseudo onset layer has a smaller grain size than the under-layer.

22. The magnetic media as in claim 15, wherein the pseudo onset layer has a grain size of 6-8 nm and the under-layer has a grain size of 8-10 nm.

23. The magnetic media as in claim 15, wherein the pseudo onset layer has a wider grain boundary than the under-layer.

24. The magnetic media as in claim 15, wherein the under-layer comprises Ru+X, where X is Ti, Ta, B, Cr or Si, and the pseudo onset layer has the same composition as the under-layer except for the addition of oxygen.

25. The magnetic media as in claim 24, wherein the concentration of X in either of the under-layer and the pseudo onset layer is not greater than 3 atomic percent.
